(19) United States
(12) Patent Application Publication
(10) Pub. No.: US 2010/0013465 A1
(43) Pub. Date: Jan. 21, 2010

(54) FORCE MEASURING DEVICE AND METHOD FOR SIGNAL EVALUATION

(75) Inventors: Sven Sautter, Reutlingen (DE); Andreas Hampe, Kirchheim (DE)

Correspondence Address: LEYDIG VOIT & MAYER, LTD, 700 THIRTEENTH ST. NW, SUITE 300, WASHINGTON, DC, 20005-3960, US

(73) Assignee: BAG BIZERBA AUTOMOTIVE GMBH, Balingen (DE)

(21) Appl. No.: 12/541,192

(22) Filed: Aug. 14, 2009

Related U.S. Application Data
(63) Continuation of application No. PCT/EP2008/051563, filed on Feb. 8, 2008.

(30) Foreign Application Priority Data
Feb. 20, 2007 (DE) 10 2007 009 389.8

(51) Int. Cl. G01B 7/14; G01R 33/12

(52) U.S. Cl. 324/207.11; 324/228

(57) ABSTRACT

A force measuring device is provided, which comprises a transducer device that has a plurality of magnets and generates a magnetic field, and a sensor device that is sensitive to a magnetic field and is arranged in a space in front of the transducer device, the transducer device and the sensor device being movable relative to each other under the action of a force, wherein the magnets of the transducer device are positioned in a quadrupole arrangement relative to the sensor device, and the sensor device comprises at least one first sensor element and one second sensor element, the first sensor element being associated with a first magnetic pole or a first pair of magnetic poles, and the second sensor element being associated with a second magnetic pole or a second pair of magnetic poles.

This application is a continuation of international application number PCT/EP2008/051563 filed on Feb. 8, 2008.

The present disclosure relates to the subject matter disclosed in international application number PCT/EP2008/051563 of Feb. 8, 2008 and German application number 10 2007 009 389.8 of Feb. 20, 2007, which are incorporated herein by reference in their entirety and for all purposes.

### BACKGROUND OF THE INVENTION

The invention relates to a force measuring device, comprising a transducer device that has a plurality of magnets and generates a magnetic field, and a sensor device that is sensitive to a magnetic field and is arranged in a space in front of the transducer device, wherein the transducer device and the sensor device are movable relative to each other under the action of a force.

The invention further relates to a method for evaluating signals in a force measuring device.

There is known from WO 2006/105902 A1 a force measuring device comprising a transducer-sensor assembly with a transducer device that generates a magnetic field and a sensor device that is sensitive to a magnetic field. The transducer device and the sensor device are movable relative to each other by force acting on the force measuring device. The transducer device comprises at least one first permanent magnet and one second permanent magnet, which each have a substantially constant geometric cross section in a longitudinal direction. The first permanent magnet and the second permanent magnet are arranged at an angle to each other.

From DE 10 2004 011 591 A1 there is known a joining element which is so configured that the joining element detects a relative motion between a magnet system and a magnet sensor apparatus for force measurement. The magnet system is arranged in relation to the magnet sensor apparatus in such a way that a component of the magnetic field perpendicular to the relative motion is linearized.

A magnetic steering angle detection apparatus is known from DE 103 44 043 A1.

There is known from DE 100 60 287 A 1 a device for measuring the angle and/or the angular velocity of a rotatable body, wherein a field-producing and/or field-changing arrangement or an arrangement that responds to the produced and/or changed field is respectively associated with the rotatable body and a stationary part of the device, and, in addition, the torque acting on the rotatable body is measured.

A magnetic displacement sensor is known from EP 1 076 225 A2.

Magnetic position detectors are also known from U.S. Pat. No. 4,936,148, U.S. Pat. No. 5,493,216, U.S. Pat. No. 6,515,474 B1 and US 2004/0239514 A1.

### SUMMARY OF THE INVENTION

In accordance with the present invention, a force measuring device is provided, which is usable in a universal manner.

In accordance with an embodiment of the invention, the magnets of the transducer device are positioned in a quadrupole arrangement relative to the sensor device, and the sensor device comprises at least one first sensor element and one second sensor element, the first sensor element being associated with a first magnetic pole or a first pair of magnetic poles, and the second sensor element being associated with a second magnetic pole or a second pair of magnetic poles.

In the solution according to the invention, the magnets are arranged in a quadrupole arrangement. In the quadrupole arrangement, two respective magnetic poles have an identical sign (north, south). A directional selectivity is thereby obtained at least in one plane. A directional selectivity is possibly also achievable perpendicularly to this plane.

The sensor device comprises several (at least two) sensor elements. A directional dependence of the force that is acting can thus be determined using the directional selectivity of the quadrupole arrangement. Alternatively or additionally, it is possible to eliminate by calculation interferences such as magnetic interference fields (particularly external magnetic interference fields) by forming a difference between sensor signals.

The solution according to the invention makes it possible, for example, to determine the x-component and y-component of a force (when the transducer device and the sensor device follow each other in a z-direction). Recognition of an angle of an acting force is thereby possible.

It is, therefore, also possible, since the angle at which the force is introduced is, in principle, optionally selectable, to mount the force measuring device (in the form of a force measuring cell, for example) with an optional mounting orientation on an application such as, for example, a vehicle seat.

Furthermore, it is, for example, possible to determine torsions of sensor device and transducer device relative to each other.

It is, furthermore, possible to evaluate a z-component of the magnetic field by a non-linear main pole approximation.

Interference fields can be compensated for by a differential path measurement evaluation or force measurement evaluation using two opposed secondary magnetic fields (brought about by the quadrupole arrangement). A high degree of measuring accuracy is thereby obtained.

It may be provided that the number of sensor elements is less than the number of magnetic poles (which is four). For example, the corresponding sensor device may comprise two sensor elements, these sensor elements each being associated with a pair of magnetic poles. Optionally, a third sensor element may be provided, which is associated with a central region of the quadrupole arrangement. It is also possible for one or two sensor elements to be associated with each magnetic pole. This results in a large number of evaluation possibilities, so that the corresponding force measuring device is universally employable and/or operates with high accuracy. Two sensor elements may be associated with a magnetic pole by the corresponding sensor element lying partly in a projection space which is associated with the one magnetic pole, and partly in the projection space which is associated with the other magnetic pole.

It is, for example, also possible for one sensor element to be associated with each pair of magnetic poles. In a quadrupole arrangement there are four pairs of magnetic poles (north pole-south pole pairs). Accordingly, the sensor device then has at least four sensor elements. With corresponding orientation of the sensor elements, assembly can then be easily optimized by opposite sensor elements being aligned in relation to a zero field line.

In particular, in the quadrupole arrangement two respective magnetic poles with the same sign face the sensor device. Two opposed secondary magnetic fields are thereby provided. If the transducer device and the sensor device follow each other in a z-direction, then two opposed secondary magnetic fields are provided both in the x-direction perpendicular to the z-direction and in the y-direction perpendicular to the z-direction and to the x-direction.

In the quadrupole arrangement, next adjacent magnetic poles have a different sign (i.e., the next adjacent magnetic poles are a north pole and a south pole, respectively). Opposed secondary magnetic fields can thereby be provided.

For the same reason, it is expedient for diagonally opposed magnetic poles in the quadrupole arrangement to have the same sign.

Expediently, the transducer device is formed by permanent magnets. The force measuring device can thus be of small, compact construction.

It may be provided that the transducer device comprises two magnets or four magnets for provision of the quadrupole arrangement. Depending on the application, optimized magnetic field conditions can thereby be provided in a compact construction.

It is quite particularly advantageous for the magnets of the transducer device to be of essentially identical configuration. Symmetrical relations are thereby achieved in a simple way. This allows simple compensation of interference fields by differential path measurement or force measurement. Furthermore, a non-linear main pole approximation can be carried out in a simple way in order to detect a z-component of a magnetic field.

In one embodiment, the transducer device comprises bar magnets whose magnetic poles lie along the longest axis of extent. An end face of such a bar magnet facing the sensor device is then a pole side (of the north pole or south pole of the bar magnet). In such a configuration, four bar magnets are required for a quadrupole arrangement.

In an alternative embodiment, the transducer device comprises magnets whose magnetic poles lie along an axis of extent, which is transverse to the longest axis of extent. In this case, an end face of the corresponding magnet facing the sensor device has both a north pole portion and a south pole portion. In this embodiment, two magnets are, in principle, adequate to form a quadrupole arrangement.

It is quite particularly advantageous for the transducer device to comprise a first center plane in relation to which the magnets are geometrically symmetrical. A high degree of symmetry is thereby provided for the quadrupole arrangement. By means of a differential evaluation, interference fields can thus be easily eliminated by calculation. Furthermore, a z-component of the magnetic field can be determined in a simple way by a non-linear main pole approximation.

The geometrical arrangement relates to the outer form of the magnets without taking the polarity into consideration.

It is then expedient for the signs of the magnetic poles to be antisymmetrical in relation to the first center plane, in order to provide a quadrupole arrangement.

For the same reason, it is expedient for the transducer device to have a second center plane which is transverse (and, in particular, perpendicular) to the first center plane in relation to which the magnets are geometrically symmetrical. A high degree of symmetry is thereby provided.

For provision of a quadrupole arrangement, the signs of the magnetic poles are antisymmetrical in relation to the second center plane.

In one embodiment it is provided that one or more magnets is or are arranged at an acute angle in relation to the first center plane and/or the second center plane. As described in WO 2006/105902 A1, a high magnetic field focusing is thereby achieved at the sensor device. This results in an improvement in the characteristics of the corresponding transducer-sensor assembly. The magnetic energy density is increased, so that a higher insensitivity to magnetic interference fields exists.

In particular, a point of intersection of axes of extent of magnets that are arranged at an acute angle lies in the space in front of the transducer device. The magnets are then arranged in the shape of a V, with the V opening out in the direction away from the sensor device.

In particular, the magnets are arranged and configured in such a way in the quadrupole arrangement that there is a central region which is at least approximately free of a magnetic field. The influence of interference fields can be determined by means of this central region which is free of a magnetic field if a sensor element is correspondingly associated with it. The interference fields can then be taken into account in the calculation when evaluating the sensor signals.

In particular, the central region that is free of a magnetic field lies at the point of intersection of a first center plane and a second center plane of the transducer device.

It is quite particularly advantageous for a central region of the quadrupole arrangement to have a sensor element of its own associated with it. The magnetic field strength at this central region can then be determined. For example, the size of external interference fields can thereby be influenced, and these interference fields can then be taken into account in the evaluation.

It is quite particularly advantageous for at least one sensor element to be associated with each magnetic pole. An x-component and a y-component of the force introduced can thereby be determined, i.e., an angle at which the force is introduced in relation to a defined axis can be determined. Furthermore, a differential evaluation with respect to both components is possible. It is, for example, also possible to determine a torsion by the signals of all sensor elements being taken into account. Furthermore, it is possible to carry out a non-linear main pole approximation in order, for example, to determine a magnetic field strength in the z-direction.

It is then expedient for the sensor device to comprise (at least) a third sensor element and a fourth sensor element. A fifth sensor element which is associated with a central region of the quadrupole arrangement may also be provided.

It is expedient for the sensor elements of the sensor device to be arranged symmetrically in relation to a first center plane. The sensor elements are thus arranged identically relative to one another so that a differential evaluation is possible in a simple way.

For the same reason, it is expedient for the sensor elements of the sensor device to be arranged symmetrically in relation to a second center plane which is transverse and, in particular, perpendicular to the first center plane.

Conditions with a high degree of symmetry are obtained by the first center plane of the sensor device coinciding with a first center plane of the transducer device when there is no relative deflection between the transducer device and the sensor device. For example, an x-component and a y-component of an acting force which brings about a deflection of the sensor device and the transducer device relative to each other can thereby be determined in a simple way.

It is also possible for the first center plane of the sensor device to lie at an angle to a first center plane of the transducer device. For example, this angle is 45°. Assembly of the sensor device and the transducer device is thereby simplified; the alignment of sensor elements associated with one another can be optimized with respect to a zero field line.

For the reason stated hereinabove, it is expedient for the second center plane of the sensor device to coincide with a second center plane of the transducer device when there is no relative deflection between transducer device and sensor device.

It may also be provided that the second center plane of the sensor device lies at an angle (such as, for example, 45°) to a second center plane of the transducer device. Sensor elements that are associated with one another can thereby be aligned in a simple way relative to a zero field line. In turn, assembly of the sensor device and the transducer device relative to each other can thereby be simplified.

In particular, sensor elements of the sensor device are arranged at the corners of a quadrilateral. This quadrilateral is preferably plane and, in particular, a rectangle. A high degree of symmetry is achieved when the quadrilateral is a square.

It is possible for the quadrilateral of the sensor device to be congruent with a quadrilateral at the corners of which the magnetic poles lie, or for the quadrilateral of the sensor device to be at an angle to the quadrilateral of the magnetic poles. Congruent means that the sides of the quadrilateral of the sensor device lie substantially parallel to the sides of the quadrilateral of the magnetic poles. The angle at which the quadrilateral of the sensor device is arranged relative to the quadrilateral of the magnetic poles is, for example, 45°. In the latter case, a simple alignability in relation to a zero field line is achievable when assembling the force measuring device.

A further sensor element may be arranged at a diagonal point of intersection of the quadrilateral. Interference fields can be measured by means of such a sensor element. The interference field results can then be taken into account in the evaluation.

Expediently, a sensor element associated with one or more magnetic poles is positioned in a projection space of the magnetic pole or poles in front of the magnetic pole or poles in the direction of the sensor device. For each permitted relative deflection between sensor device and transducer device, a sensor element signal can then be provided, which can be correspondingly linked to other sensor element signals in order, for example, to be able to carry out a differential evaluation.

In an embodiment which is simple in terms of manufacturing technology, the sensor elements are Hall elements. The corresponding force measuring device can be constructed in a compact manner. It is, for example, thus possible to measure deflections in the micrometer range.

It is expedient for an evaluation device to be provided for linking the signals of different sensor elements. For example, a differential evaluation and/or an addition can then be carried out. Various signal evaluations can be carried out in order, for example, to determine the x-component and the y-component of a force, in order to eliminate interference fields by calculation, in order to determine torsions, and in order to carry out a non-linear main pole approximation.

It is then expedient for the evaluation device to comprise a differential unit for forming a difference between signals of different sensor elements. A differential force measurement or path measurement can thus be carried out. This makes it possible to provide signals of high accuracy with elimination of interferences. Furthermore, it is possible to determine an angle at which a force is introduced.

It may also be provided that the evaluation device comprises an adding unit for adding up signals of different sensor elements. A non-linear main pole approximation can be carried out by adding sensor signals of diagonally opposed sensor elements, possibly taking the influence of interference fields into account. The z-component of the acting magnetic field can be determined with the main pole approximation.

In one embodiment, the transducer device or the sensor device is connected to an elastic force transducer. Forces which result in an elastic deformation are introduced through the elastic force transducer either directly or by a force introduction device. The elastic deformation results in a relative movement between the transducer device and the sensor device; the transducer device and the sensor device are deflected relative to each other in relation to a zero position. This deflection results in a change in the magnetic field acting on the sensor device. From this change it is, in turn, possible to determine the deflection and from this the force.

In one embodiment, the force transducer is configured as a hollow bar.

It is then expedient for the transducer device and the sensor device to be arranged in an interior of the hollow bar. With the solution according to the invention, it is possible to introduce the force over a total circumferential area, and the angle at which force is introduced relative to a predefined radial axis can be determined.

In accordance with the present invention, a method for evaluating signals in a force measuring device is provided.

In an embodiment of the invention, a difference is formed between signals of different sensor elements and/or a magnetic field in a central region of the quadrupole arrangement is measured by a sensor element associated with the central region, and/or the signals of diagonally opposed sensor elements are evaluated.

In the method according to the invention, signals can be provided, in which interferences are eliminated by the difference formation. Furthermore, a directional evaluation of the force introduced can be carried out by the difference formation. By measuring the magnetic field in a central region of the quadrupole arrangement, in particular, external interference fields can be measured and taken into account in the evaluation of the sensor signals. By evaluating signals of diagonally opposed sensor elements, it is possible to determine a magnetic field component in a z-direction (in which the transducer device and the sensor device follow each other) by non-linear main pole approximation.

In particular, a difference is formed with the signals of a first pair of sensor elements and the signals of a second pair of sensor elements, with a direction of connection between the sensor elements of the first pair lying transversely (and, in particular, perpendicularly) to the direction of connection between the sensor elements of the second pair. A differentiation between a first force component and a linearly independent second force component of the acting force is thereby possible. As a result, an angle at which a force is introduced can be determined, and it does not matter in which orientation the force measuring device is installed.

For example, the signals of four sensor elements positioned at the corners of a quadrilateral are evaluated. In particular, the quadrilateral is plane. It has a normal direction, which is parallel to the direction in which the transducer device and the sensor device follow each other. Torsions can thereby be determined (in relation to an axis of rotation which is parallel to the normal axis of the quadrilateral).

It may also be provided that a main pole approximation is carried out. To this end, in particular, the signals of diagonally opposed sensor elements are evaluated.

For example, the signals of diagonally opposed sensor elements are evaluated by performing an addition. A z-component of the magnetic field can thereby be determined at least approximately.

It is expedient for an interference field in a central region of the quadrupole arrangement to be measured and taken into account in the evaluation. Identical interferences can be eliminated by forming a difference between signals of different sensor elements. This can also be explicitly allowed for, for example, in a non-linear main pole approximation by the measurement of the central interference field.

The following description of preferred embodiments serves in conjunction with the drawings to explain the invention in greater detail.

### BRIEF DESCRIPTION OF THE DRAWINGS

FIG. 1 shows a sectional view of an embodiment of a force measuring device according to the invention;

FIG. 2 shows a schematic representation of an embodiment of a magnet arrangement on a transducer device;

FIG. 3 shows a schematic representation of a plan view of a sensor device and transducer device;

FIG. 4 shows a schematic side view of the transducer device and sensor device in accordance with FIG. 3 in the direction A;

FIG. 5 shows a representation of the magnetic field configuration for the transducer device in accordance with FIG. 3;

FIG. 6 shows a second embodiment of a magnet arrangement;

FIG. 7 shows a third embodiment of a magnet arrangement;

FIG. 8 shows a fourth embodiment of a magnet arrangement;

FIG. 9 shows a fifth embodiment of a magnet arrangement;

FIG. 10 shows a variant of an embodiment of a force measuring device in partial representation with a transducer device corresponding to the embodiment in accordance with FIG. 2 and a modified sensor device;

FIG. 11 shows a schematic representation of the relative position of transducer device and sensor device upon rotation (torsion);

FIG. 12 shows a schematic representation of the relative position between transducer device and sensor device upon linear z-movement relative to each other; and

FIG. 13 shows the relative position between transducer device and sensor device upon rotation of the sensor device about an axis parallel to the y-axis.

### DETAILED DESCRIPTION OF THE INVENTION

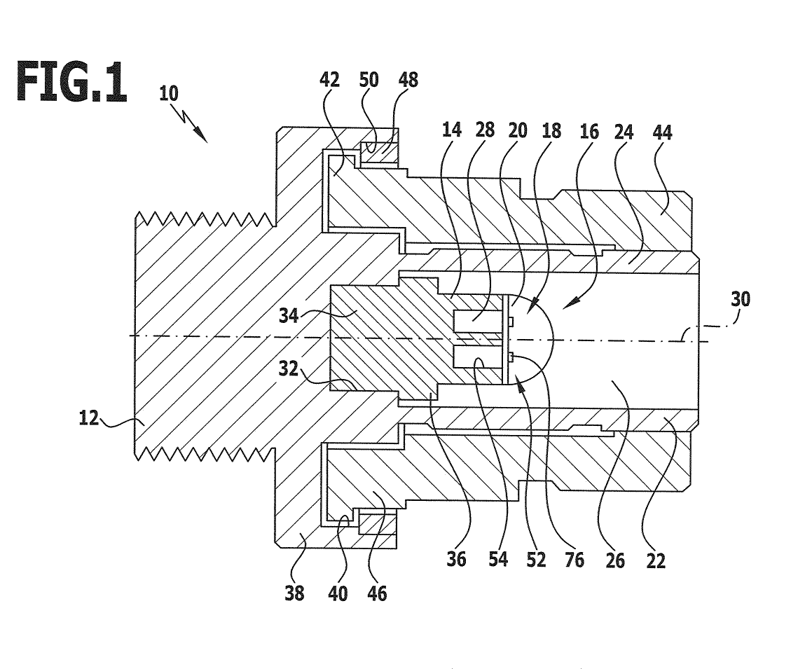

An embodiment of a force measuring device according to the invention, which is shown in a sectional view in FIG. 1 and is designated therein by 10, is configured, in particular, as a force measuring cell. The force measuring device 10 comprises a mounting part 12, which holds a transducer device 14 of a transducer-sensor assembly 16.

The transducer-sensor assembly 16 comprises in addition to the transducer device 14 a sensor device 18 with a plurality of sensor elements that are sensitive to a magnetic field, as will be explained in greater detail hereinbelow. The sensor device 18 is arranged in a space 20 in front of the transducer device 14.

The force measuring device 10 can be secured by means of the mounting part 12 to an application. For example, the force measuring device 10 is intended for mounting on a vehicle and, in particular, a motor vehicle. The force measuring device 10 is mounted, for example, on the upper rail of a vehicle seat mounting by means of the mounting part 12.

An elastically configured force transducer 22 is seated on the mounting part 12. This is configured, in particular, as a hollow bar 24. The hollow bar 24 has an interior 26. The space 20 is part of the interior 26. The sensor device 18 and magnets 28 of the transducer device 14 that generates a magnetic field are positioned in the interior 26.

The hollow bar 24 extends in a longitudinal direction 30. The interior 26 is, for example, cylindrical with an axis coinciding with the longitudinal direction 30.

It may be provided that the force transducer 22 has weakening zones which are formed, for example, by recesses on an outer side of the hollow bar 24. For example, two weakening zones spaced in the longitudinal direction are provided. The weakening zones may be ring-shaped or in the shape of the envelope of a cone. Articulation points that give the force transducer 22 the function of a parallelogram force transducer are formed by the weakening zones.

The transducer device 14 is secured in a, for example, cylindrical recess 32 of the mounting part 12. For this purpose, the transducer device 14 has a retaining base 34. A holding device 36 for the magnets 28 is seated on the retaining base.

The transducer device 14 is positioned without contact with the hollow bar 24 in its interior 26.

The mounting part 12 has a ring-shaped flange 38 with a ring-shaped recess 40. A force introduction device 24, by means of which forces can be introduced into the force transducer 22, is positioned in the recess 40. The force introduction device 42 is seated with play in the recess 40.

The force introduction device 42 is, for example, of hollow-cylindrical configuration and lies coaxially with the force transducer 22. It has a force introduction region 44, which holds a free end region of the force transducer 22. The force transducer 22 is held by means of its other end region on the mounting part 12.

In addition, the force introduction device 42 has a holding end region 46, which enters the recess 40 of the mounting part 12. So long as permissible forces act on the force introduction device 42, it can move unhindered in the recess 40 on account of the play. If the acting forces become impermissibly high, then a stop ring 48, which is arranged between the holding end region 46 and a wall of the flange 38 delimiting the recess 40, prevents any further movement of the force introduction device 42 and thereby prevents any damage to the force transducer 22.

The stop ring 48 is secured, for example, by laser welding to the mounting part 12. It may be arranged in a corresponding recess 50 of the mounting part 12, which adjoins the recess 40.

The force transducer 22 is elastically deformable. It can, therefore, take up forces such as weight forces, for example.

The sensor device 18 is connected to the force transducer 22 (not shown in FIG. 1), so that if forces are introduced through the force transducer 22, the sensor device 18 is moved relative to the transducer device 14 and/or the sensor device 18 is deflected relative to the transducer device 14 in relation to a zero position.

The sensor device 18 has a holder 52 on which sensor elements are seated. This holder 52 is connected to the force transducer 22, so that deformation of the elastic force transducer 22 results in deflection of the holder 52 and hence of the sensor elements arranged thereon relative to the transducer device 14. This relative deflection is a deflection relative to the magnets 28 of the transducer device 14, so that the magnetic field acting on the sensor device 18 is changed. The force acting on the force transducer 22 can be determined from this change in the magnetic field (in relation to the magnetic field when the sensor device 18 is in a non-deflected position relative to the transducer device 14).

In the solution according to the invention, which can also be implemented as a path measurement device or a pressure measurement device, a path or a pressure can also be determined from the relative deflection between the sensor device 18 and the transducer device 14.

The magnets 28 of the transducer device 14 are arranged, for example, in recesses 54 of the holding device 36 of the transducer device 14.

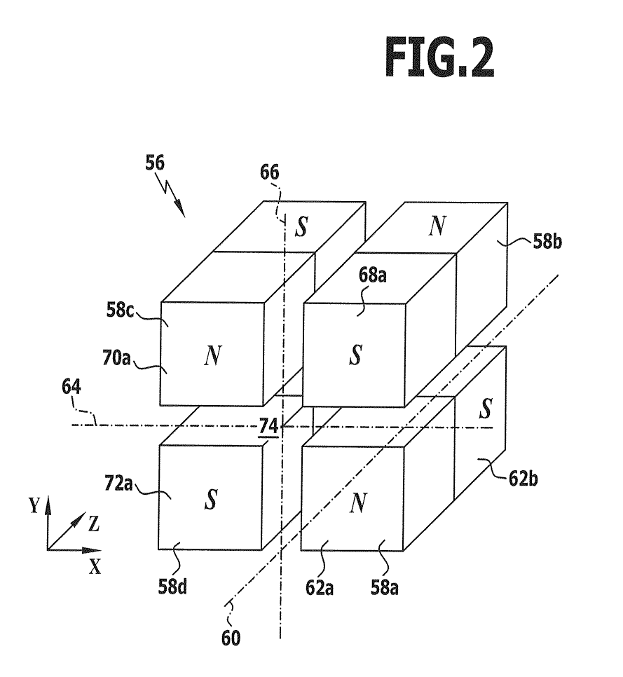

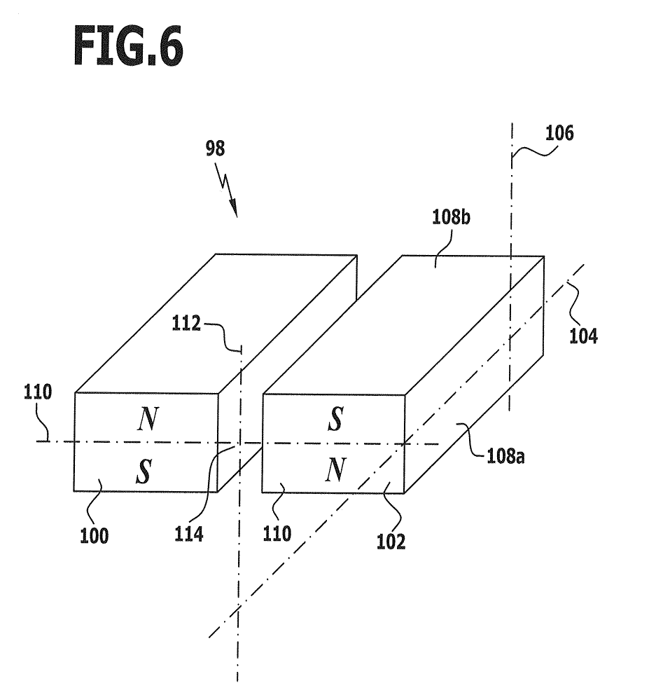

The transducer device 14 comprises a quadrupole arrangement 56 of the magnets 28 (FIG. 2 or FIG. 6, for example). Such a quadrupole arrangement 56 can be implemented by two magnets or by four magnets.

In the quadrupole arrangement 56, the transducer device 14 comprises four spaced magnets 58a, 58b, 58c, 58d. These magnets are configured as permanent magnets. For example, the magnets 58a, 58b, 58c, 58d are bar magnets which extend in a direction of extent 60. The magnets 58a, 58b, 58c, 58d are each of cuboidal configuration. This direction of extent 60 is the longest direction of extent. The magnets have, for example, a square cross section transversely to the direction of extent 60.

Between next adjacent magnets (58a, 58b; 58b, 58c; 58c, 58d; 58d, 58a) there lies in each case a small air gap (shown disproportionately large in FIGS. 2 to 4), whose width lies, for example, in the order of magnitude of 1 mm. (The term air gap relates to the magnetic field; the gap may be filled out by a solid body material.)

Magnetic poles 62a, 62b (north pole, south pole) follow each other in the longest direction of extent 60.

The magnets 58a, 58b, 58c, 58d are preferably of geometrically identical configuration. They are geometrically symmetrical with a first center plane 64. The longitudinal direction 30 passes through the first center plane 64. They are also geometrically symmetrical with a second center plane 66, which is transverse and, in particular, perpendicular to the first center plane 64. The longitudinal direction 30 also passes through the second center plane 66 and coincides, in particular, with a line of intersection of the first center plane 64 and the second center plane 66. The longest direction of extent 60 of the magnets 58a, 58b, 58c, 58d is parallel to both the first center plane 64 and the second center plane 66.

The magnet 58a has a magnetic pole 62a facing into the space 20 in front of the transducer device. Furthermore, the magnet 58b has a magnetic pole 68a facing into the space 20. The magnet 58c has a magnetic pole 70a facing into the space 20. The magnet 58d has a magnetic pole 72a facing into the space 20. The magnetic poles 62a, 68a, 70a and 72a are arranged antisymmetrically in relation to the first center plane 64 and the second center plane 66, i.e., the sign of the magnetic poles is antisymmetrical in relation to the first center plane 64 and the second center plane 66. (In this context, sign of a magnetic pole is to be understood as allocation of a positive value, for example, to the north pole and a negative value to the south pole.) Accordingly, next adjacent magnetic poles (such as magnetic poles 62a and 68a, magnetic poles 68a and 70a, magnetic poles 70a and 72a and magnetic poles 72a and 62a) have a different sign. Diagonally opposed magnetic poles (such as magnetic poles 70a, 62a and 68a, 72a) have the same sign. The magnetic poles 62a, 68a, 70a, 72a have an alternating sign in a “rotating direction”.

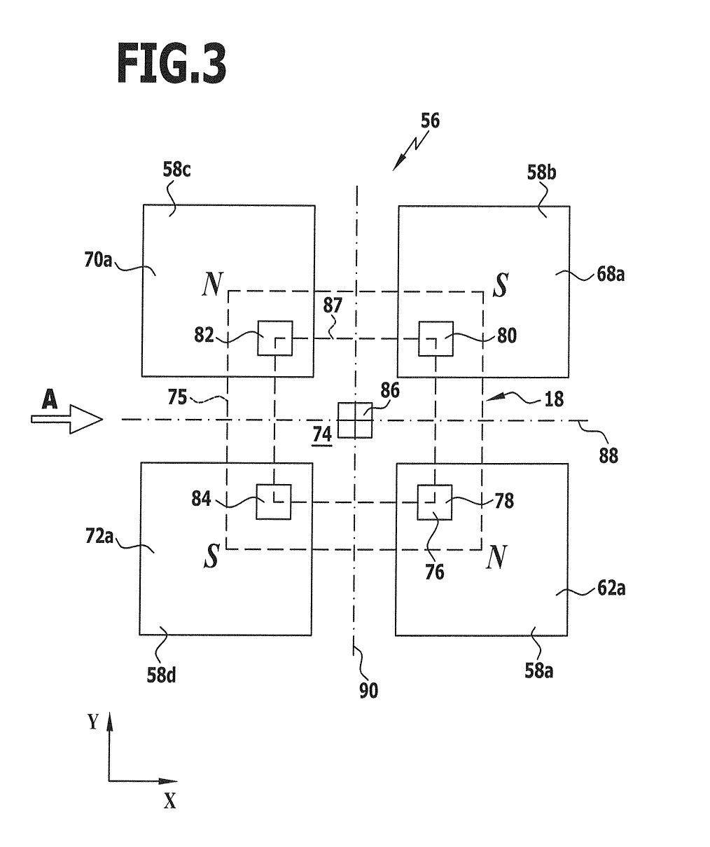

The magnetic poles 62a, 68a, 70a, 72a lie with their center at the corners of a quadrilateral 75 (FIG. 3). This quadrilateral 75 is, in particular, a (plane) rectangle and preferably a square. The center planes 64 and 66 are center planes of this quadrilateral 75.

The quadrupole arrangement 56 has a central region 74 in the area of the line of intersection of the first center plane 64 and the second center plane 66, which is at least approximately free of a magnetic field.

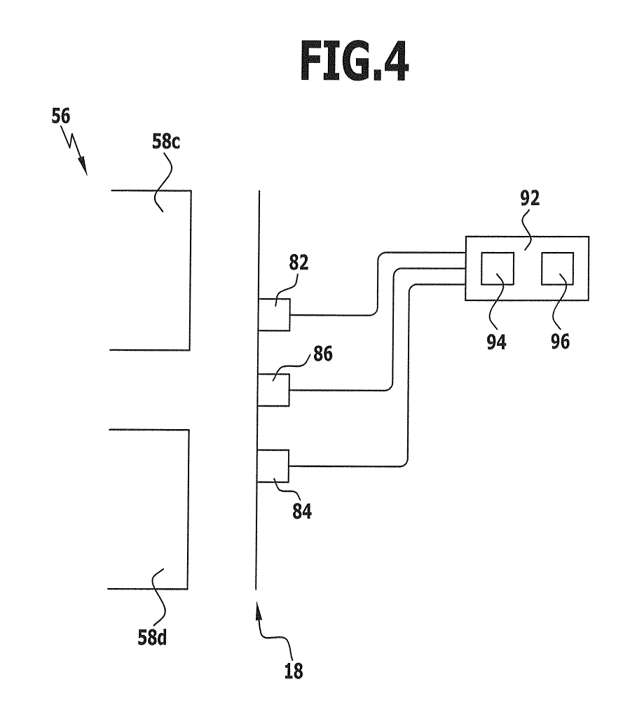

The sensor device 18 comprises a plurality of sensor elements 76 (FIGS. 3 and 4), each magnetic pole 62a, 68a, 70a, 72a having a sensor element of its own associated with it: associated with the magnetic pole 62a is a first sensor element 78, associated with the magnetic pole 68a is a second sensor element 80, associated with the magnetic pole 70a is a third sensor element 82, and associated with the magnetic pole 72a is a fourth sensor element 84. Furthermore, a fifth sensor element 86 is associated with the central region 74.

The sensor elements 78, 80, 82 and 84 are arranged in a projection space in front of the respective associated magnetic poles. They are positioned in such a way that the magnetic field strength can be detected for all possible deflections of the sensor device 18 relative to the transducer device 14, thereby enabling a reliable force measurement.

The sensor elements 78, 80, 82, 84 are also positioned with their center at the corners of a quadrilateral 78 and, in particular, a square. The fifth sensor element 86 lies on the diagonal of this quadrilateral.

The sensor elements 78, 80, 82 and 84 are arranged symmetrically in relation to a first center plane 88 and symmetrically in relation to a second center plane 90, the second center plane 90 being orientated transversely and, in particular, perpendicularly to the first center plane 88.

At a zero setting of the sensor device 18 when the force transducer 22 is not acted upon by a force, the first center plane 88 coincides with the first center plane 64 of the transducer device 14, and the second center plane 90 coincides with the second center plane 66 of the transducer device 14.

The quadrilateral 75 of the quadrupole arrangement 56 and the quadrilateral 87 of the sensor device 18 are congruent to each other, i.e., they have parallel sides.

The force measuring device 10 comprises an evaluation device 92 or an evaluation device 92 is associated with the force measuring device 10 (FIG. 4). The evaluation device can be arranged outside of a housing of the force measuring device 10 and, in particular, outside of the hollow bar 24, or it can be arranged inside the housing. For example, it is arranged in the interior 26 of the hollow bar 24.

The signals of the different sensor elements 78, 80, 82, 84, 86 are linked to the evaluation device 92. For example, a differential path measurement or force measurement can thereby be carried out. It is, for example, also possible to take into account and compensate for interference fields.

The evaluation device 92 comprises, for example, a differential unit 94 for determining a difference between signals of different sensor elements (such as sensor elements 78 and 80 and 82 and 84 or sensor elements 78 and 84 and 80 and 82). The evaluation device 92 further comprises an adding unit 96 for adding up the signals of different sensor elements.

The force measuring device 10 according to the invention with the quadrupole arrangement 56 operates as follows:

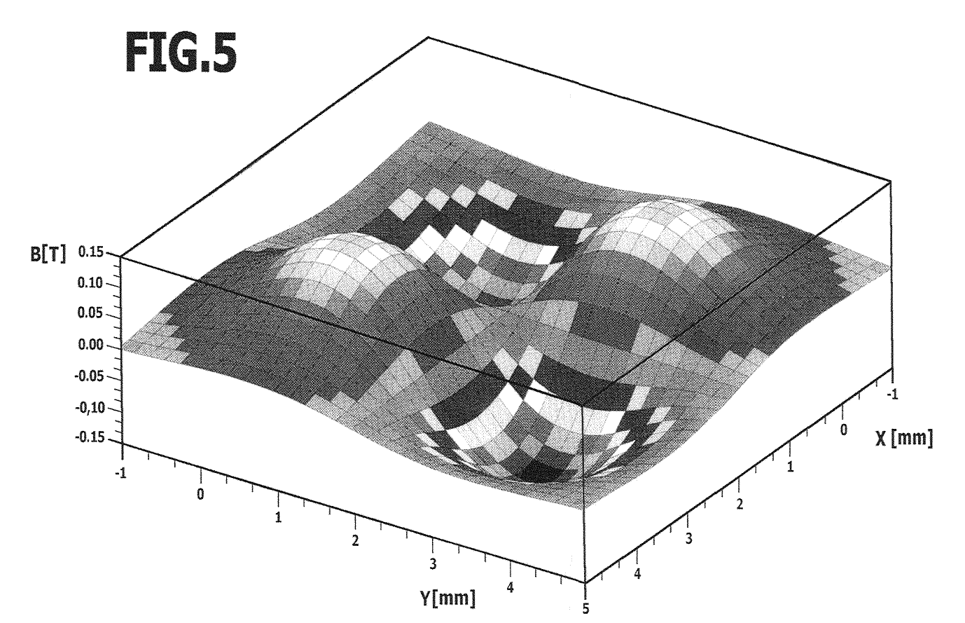

The field configuration is shown an x-y plane in FIG. 5. The x-y-z coordinate system is drawn in FIG. 2. The x-y plane is that plane to which the longitudinal direction 30 and the longest direction of extent 60 of the magnets extend perpendicularly. The x-y plane lies perpendicular to the first center plane 64 and perpendicular to the second center plane 66. The z-position of the magnetic field configuration is the one at the sensor device 18.

The air gap between the magnets of the quadrupole arrangement 56 was 1 mm.

The “hills” in the field configuration in accordance with FIG. 5 correspond to the magnetic poles 70a and 62a (north poles); the valleys correspond to the magnetic poles 72a and 68a (south poles).

The sensor elements 78, 80, 82, 84 and 85 are sensitive to a magnetic field. For example, these sensor elements are configured as Hall sensor elements. In particular, the sensor elements are formed by Hall plates. The Hall plates are orientated such that the side thereof which has the greatest height is aligned parallel to the x-y plane.

Both the x-component and the y-component of a force acting on the force transducer 22 can be determined by corresponding evaluation or both an x-path determination and a y-path determination can be carried out. The force can thereby be determined even at any angle at which the force is introduced into the force transducer 22. Consequently, the orientation at which the force measuring device 10 is installed is, in principle, optional.

The first sensor element 78 and the second sensor element 80 have a direction of connection, which is a direction of the normal to the first center plane 88. Similarly, the direction of connection of the third sensor element 82 and the fourth sensor element 84 is a direction of the normal to the first center plane 88. A direction of connection of the second sensor element 80 and the third sensor element 82 and of the fourth sensor element 84 and the first sensor element 78 is a direction of the normal to the second center plane 90. The x-component of an acting force can be obtained by forming a difference (carried out by the differential unit 94) between the signals of the sensor elements 82 and 84 and 80 and 78, respectively. The y-component can be obtained by forming a difference between the signals of the sensor elements 80 and 82 and 78 and 84, respectively. Interference components contained in the same amount in the sensor signals can also be eliminated by the difference formation.

An interference magnetic field such as, for example, an external interference magnetic field in the central region 74 of the transducer device 14 can be determined by the fifth sensor element 86 and taken into account in the signal evaluation.

A torsion, for example, can also be determined by evaluating the signals of the four sensor elements 78 to 84. A torsion can be a rotation about the z-axis perpendicular to the x-direction and y-direction or also a rotation about an axis in the x-y plane.

Furthermore, the z-component of the magnetic field can be determined by a non-linear main pole approximation. For example, the signals of diagonally opposed sensor elements (such as, for example, signals of the first sensor element 78 and the third sensor element 82 or signals of the second sensor element 80 and the fourth sensor element 84) are added up by the adding unit 96. The non-linear main pole approximation can be carried out by measuring an interference field by means of the fifth sensor element 86 and taking this interference field into account in the evaluation.

A force measuring device 10 for determining x-components and y-components of acting forces can be provided by the solution according to the invention. A separate x-path measurement and y-path measurement can be carried out. Interference fields can be compensated for by a differential evaluation. Interference fields in the central region 74 can be measured by the fifth sensor element 86 and, for example, taken into account in a non-linear main pole approximation for evaluating the z-component of the magnetic field.

Forces which act in more than one direction on the force transducer 22 can be measured (and also differentiated in their direction) by the force measuring device 10.

Furthermore, a high degree of accuracy of the measurement can be achieved.

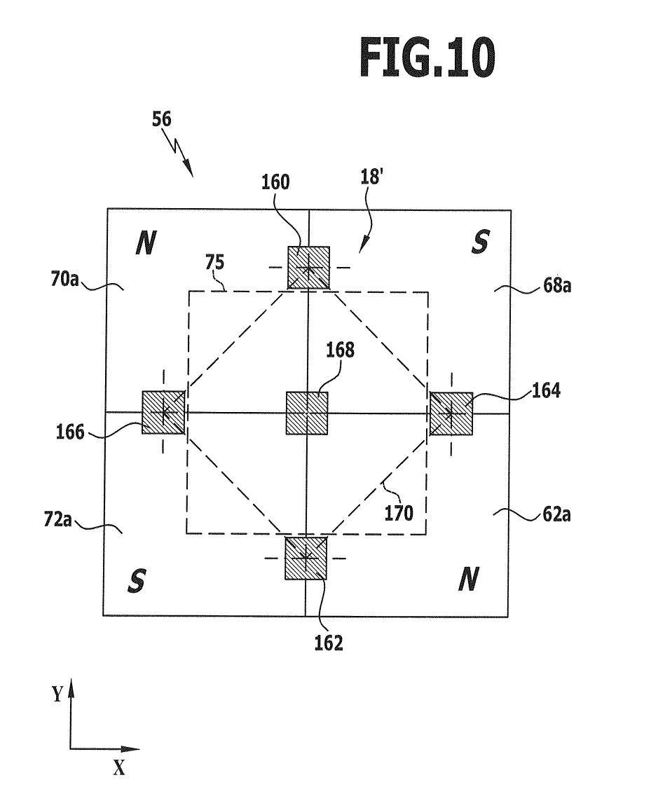

In the embodiment in accordance with FIG. 3, each magnetic pole has exactly one sensor element of its own associated with it. It is also possible for each pair of magnetic poles to have a sensor element of its own associated with it. In an embodiment of a corresponding sensor device 18′, which is shown schematically in FIG. 10, one sensor element is associated with a pair of magnetic poles. Herein the arrangement of the magnetic poles corresponds to the quadrupole arrangement 56. Accordingly, identical reference numerals are used. The magnetic poles 68a and 70a form a first pair of magnetic poles. The magnetic poles 62a and 72a form a second pair of magnetic poles. The magnetic poles 62a and 68a form a third pair of magnetic poles, and the magnetic poles 70a and 72a form a fourth pair of magnetic poles. Associated with the first pair of magnetic poles 68a, 70a is a first sensor element 160. Associated with the second pair of magnetic poles 62a, 72a is a second sensor element 162. Associated with the third pair of magnetic poles 62a, 68a is a third sensor element 164. Associated with the fourth pair of magnetic poles 70a, 72a is a fourth sensor element 166. A fifth sensor element 168 is associated with the central region 74 of the quadrupole arrangement 56.

In a non-deflected state of the sensor device 18′ in relation to the quadrupole arrangement 56, the corresponding sensor elements lie in the projection spaces of the magnetic poles with which they are associated. For example, the first sensor element 160 is acted upon by the field of both magnetic pole 68a and magnetic pole 70a, and in the non-deflected state the first sensor element 160 is arranged symmetrically with the magnetic pole 68a and the magnetic pole 70a. The other sensor elements 162, 164 and 166 are arranged in the same symmetrical way in relation to the corresponding magnetic poles.

The sensor elements 160, 162, 164, 166 lie at the corners of a quadrilateral 170. This quadrilateral 170 is rotated in relation to the quadrilateral 75. In the embodiment shown in FIG. 10, the angle of rotation is 45°. Therefore, the sides of the quadrilateral 75 and the quadrilateral 170 are not parallel. Accordingly, the center planes of the sensor device 18′ do not coincide with the center planes 64 and 66 of the quadrupole arrangement 56, but are rotated in relation to this (for example, through an angle of 45°).

With the sensor device 18′, it is possible when mounting the corresponding force measuring device to align corresponding pairs of sensor elements (first sensor element 160 and second sensor element 162; third sensor element 164 and fourth sensor element 166) in a simple way on the zero field line.

In other respects, the corresponding force measuring device operates as described hereinabove.

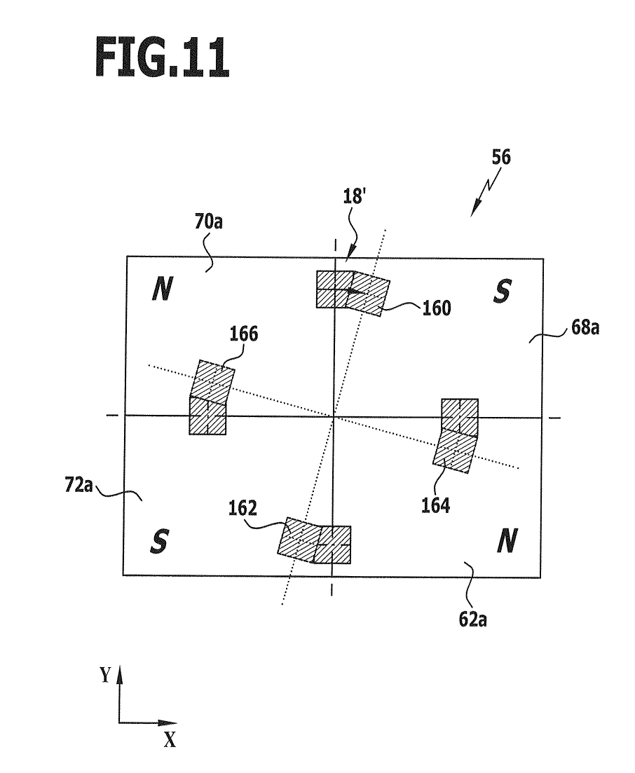

For example, rotations of the sensor device 18′ relative to the quadrupole arrangement 56 can be determined by processing the sensor signals. This is indicated in FIG. 11.

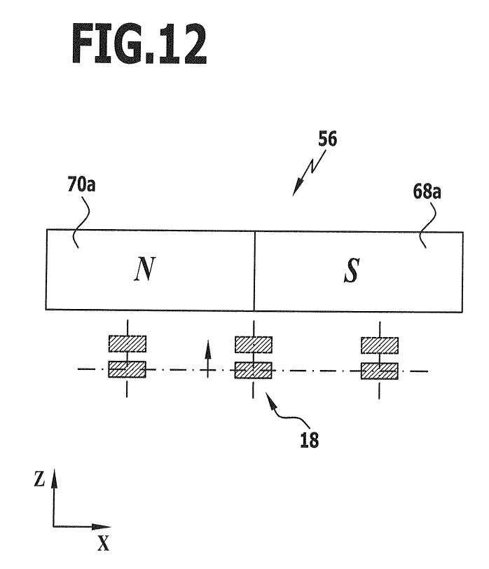

Furthermore, it is possible to determine the distance (in the y-direction) between the sensor device 18 and the quadrupole arrangement 56. This is indicated in FIG. 12.

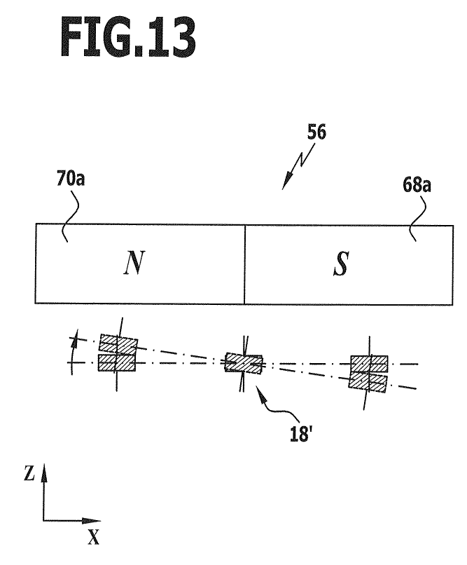

Using a non-linear multipole approximation, for example, it is also possible to determine a rotation of the sensor device 18′ relative to the quadrupole arrangement 56, in particular, about an axis parallel to the y-axis. This is indicated in FIG. 13.

In a second embodiment of a quadrupole arrangement, which is shown in FIG. 6 and designated therein by 98, a first magnet 100 and a second magnet 102 are arranged in spaced parallel relation to each other. The two magnets 101 and 102 are permanent magnets which are of cuboidal configuration. They each have a longest direction of extent 104. Transversely to this longest direction of extent they have a direction of extent 106. The magnetic poles with a different sign (north pole and south pole) 108a, 108b follow each other in this direction of extent 106. A respective end face 110 of the magnets 100 and 102 faces into the space 20 in front of the transducer device 14.

The magnets 100 and 102 of the quadrupole arrangement 98 are geometrically symmetrical with a first center plane 111 and with a second center plane 112 extending transversely thereto. The magnetic poles 108a, 108b are antisymmetrical with these center planes 111 and 112 with respect to their sign; north pole and south pole follow each other alternately, with adjacent magnetic poles having different signs and diagonally opposed magnetic poles having the same sign.

In the quadrupole arrangement 98, the quadrupole field which faces the sensor device 18 is implemented by two magnets 100, 102 instead of four magnets as in the quadrupole arrangement 56.

The sensor device 18 is basically of the same design as described hereinabove. It is also possible for the sensor device to not allocate to each magnetic pole a sensor element of its own, but for a sensor element to be associated with a pair of magnetic poles. In this case, a first sensor element and a second sensor element are provided. A further sensor element can be associated with a central region 114 of the quadrupole arrangement 98. For example, the first magnet 100 and the second magnet 102 each have a sensor element of their own associated with them.

In this solution, a differential measurement can be carried out in order, for example, to compensate for interference fields.

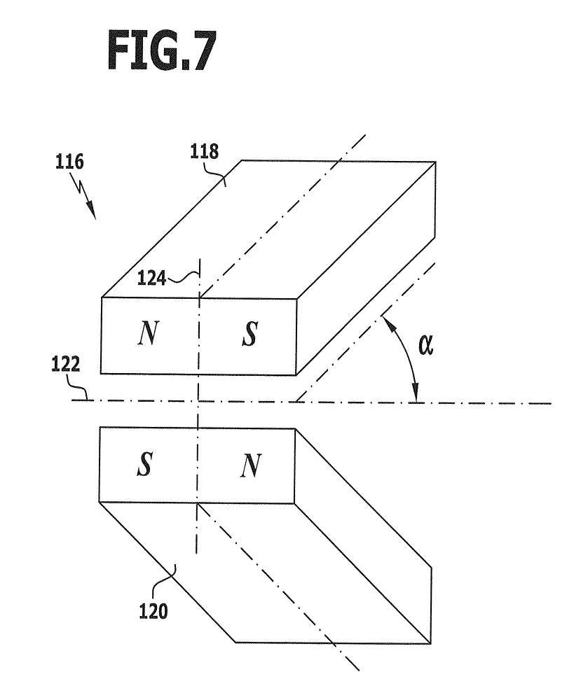

In a third embodiment of a quadrupole arrangement, which is shown in FIG. 7 and designated therein by 116, a first magnet 118 and a second magnet 120 are provided. These are arranged symmetrically with a first center plane 122 and a second center plane 124 extending transversely thereto. The first magnet 118 and the second magnet 120 are inclined at an acute angle α to the first center plane 122. They are, therefore, arranged in the shape of a V. A high magnetic field focusing can be achieved by such an angular arrangement. The characteristics of the transducer-sensor assembly can thereby be improved. The magnetic energy density is increased, so that the transducer-sensor assembly is insensitive to magnetic interference fields.

When four permanent magnets are provided as in the quadrupole arrangement 56, it is, in principle, also possible for there to also be an inclination at an acute angle to the second center plane 124.

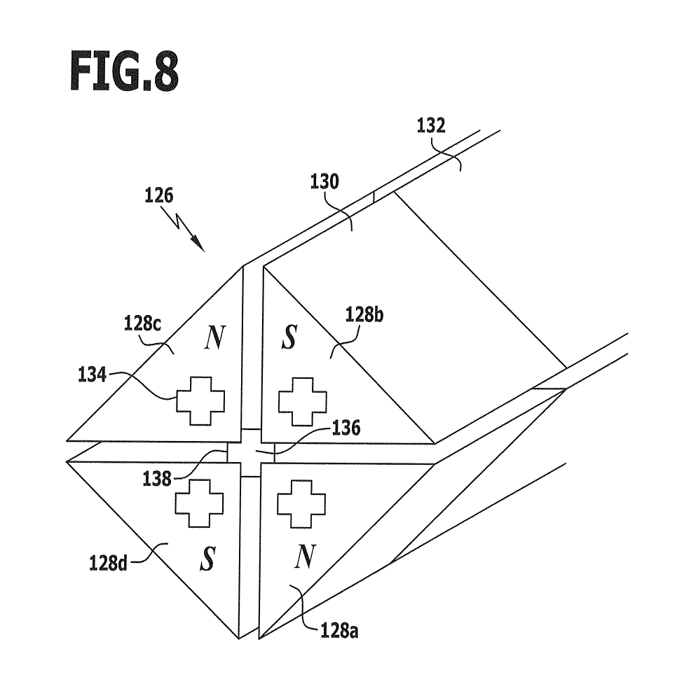

In a fourth embodiment of a quadrupole arrangement, which is shown in FIG. 8 and designated therein by 126, four bar magnets 128a, 128b, 128c, 128d are provided. These have magnetic poles 130, 132 following each other in the longest direction of extent.

The bar magnets 128a, 128b, 128c, 128d each have a triangular cross section. The corresponding triangle is a right-angled isosceles triangle. The bar magnets 128a, 128b, 128c, 128d are arranged so that the shorter triangle sides of adjacent bar magnets (128a, 128b; 128b, 128c; 128c, 128d; 128d, 128a) are in spaced parallel relation to one another.

Each magnetic pole 130 has a sensor element 134 of its own associated with it. Furthermore, a central region 136 has a sensor element 138 of its own associated with it.

The quadrupole arrangement 126 can be constructed in a compact manner with small transverse dimensions.

In other respects, the corresponding force measuring device operates as described hereinabove.

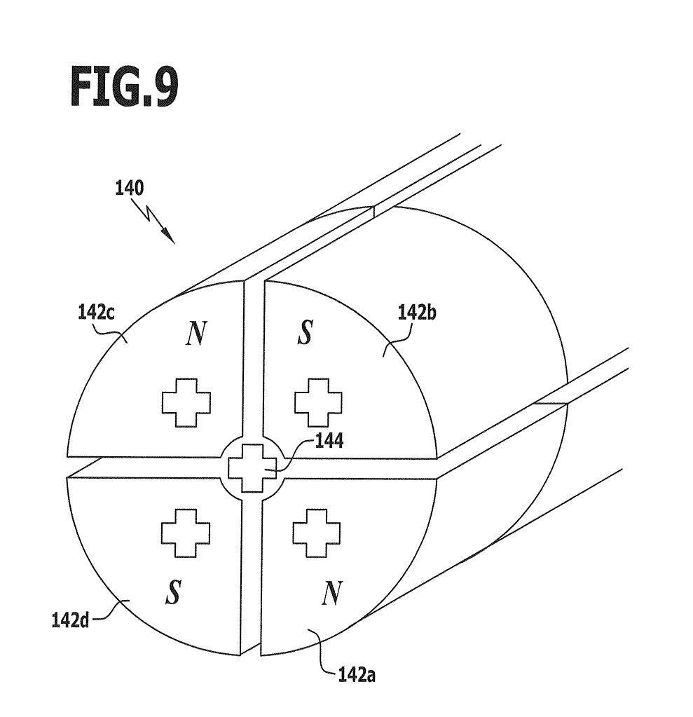

In a fifth embodiment of a quadrupole arrangement, which is shown in FIG. 9 and designated therein by 140, bar magnets 142a, 142b, 142c, 142d are provided, which have a cross section which corresponds at least approximately to a quadrant with a central region 144 removed. The bar magnets 142a, 142b, 142c, 142d are put together in such a way that the quadrupole arrangement 140 has an outer circumference cross-sectional line which is substantially circular.

Again, each magnetic pole has a sensor element of its own associated with it, and the central region 144 also has a sensor element of its own associated with it.

The construction of the quadrupole arrangement 140 corresponds to that of the quadrupole arrangement 126, but with a different cross-sectional configuration of the individual bar magnets 142a, 142b, 142c, 142d.

In other respects, the quadrupole arrangement 140 operates as described hereinabove.

1. A force measuring device, comprising:
a transducer device that has a plurality of magnets and generates a magnetic field; and
a sensor device that is sensitive to a magnetic field and is arranged in a space in front of the transducer device;
wherein the transducer device and the sensor device are movable relative to each other under the action of a force;
wherein the magnets of the transducer device are positioned in a quadrupole arrangement relative to the sensor device; and
wherein the sensor device comprises at least one first sensor element and one second sensor element;
wherein the first sensor element is associated with a first magnetic pole or a first pair of magnetic poles; and
wherein the second sensor element is associated with a second magnetic pole or a second pair of magnetic poles.

2. The force measuring device in accordance with claim 1, wherein one sensor element or two sensor elements is or are associated with each magnetic pole of the quadrupole arrangement.

3. The force measuring device in accordance with claim 1, wherein one sensor element is associated with each pair of magnetic poles of the quadrupole arrangement.

4. The force measuring device in accordance with claim 1, wherein two respective magnetic poles with the same sign in the quadrupole arrangement face the sensor device.

5. The force measuring device in accordance with claim 1, wherein next adjacent magnetic poles in the quadrupole arrangement have a different sign.

6. The force measuring device in accordance with claim 1, wherein diagonally opposed magnetic poles in the quadrupole arrangement have the same sign.

7. The force measuring device in accordance with claim 1, wherein the transducer device is formed by permanent magnets.

8. The force measuring device in accordance with claim 1, wherein the transducer device comprises two magnets or four magnets.

9. The force measuring device in accordance with claim 1, wherein the magnets of the transducer device are of essentially identical configuration.

10. The force measuring device in accordance with claim 1, wherein the transducer device comprises bar magnets whose magnetic poles lie along the longest axis of extent.

11. The force measuring device in accordance with claim 1, wherein the transducer device comprises magnets whose magnetic poles lie along an axis of extent, which is transverse to the longest axis of extent.

12. The force measuring device in accordance with claim 1, wherein the transducer device has a first center plane in relation to which the magnets are geometrically symmetrical.

13. The force measuring device in accordance with claim 12, wherein the signs of the magnetic poles are antisymmetrical in relation to the first center plane.

14. The force measuring device in accordance with claim 12, wherein the transducer device has a second center plane which is transverse to the first center plane in relation to which the magnets are geometrically symmetrical.

15. The force measuring device in accordance with claim 14, wherein the signs of the magnetic poles are antisymmetrical in relation to the second center plane.

16. The force measuring device in accordance with claim 12, wherein one or more magnets is or are arranged at an acute angle in relation to at least one of the first center plane and the second center plane.

17. The force measuring device in accordance with claim 16, wherein a point of intersection of axes of extent of magnets that are arranged at an acute angle lies in the space in front of the transducer device.

18. The force measuring device in accordance with claim 1, wherein the magnets are arranged and configured in such a way that there is a central region that is at least approximately free of a magnetic field.

19. The force measuring device in accordance with claim 18, wherein the central region that is free of a magnetic field lies at the point of intersection of a first center plane and a second center plane of the transducer device.

20. The force measuring device in accordance with claim 1, wherein a central region of the quadrupole arrangement has a sensor element of its own associated with it.

21. The force measuring device in accordance with claim 1, wherein at least one sensor element is associated with each magnetic pole.

22. The force measuring device in accordance with claim 21, wherein the sensor device comprises a third sensor element and a fourth sensor element.

23. The force measuring device in accordance with claim 1, wherein the sensor elements of the sensor device are arranged symmetrically in relation to a first center plane.

24. The force measuring device in accordance with claim 23, wherein the sensor elements of the sensor device are arranged symmetrically in relation to a second center plane which is transverse to the first center plane.

25. The force measuring device in accordance with claim 23, wherein the first center plane of the sensor device coincides with a first center plane of the transducer device when there is no relative deflection between transducer device and sensor device.

26. The force measuring device in accordance with claim 23, wherein the first center plane of the sensor device lies at an angle to a first center plane of the transducer device.

27. The force measuring device in accordance with claim 23, wherein the second center plane of the sensor device coincides with a second center plane of the transducer device when there is no relative deflection between transducer device and sensor device.

28. The force measuring device in accordance with claim 23, wherein the second center plane of the sensor device lies at an angle to a second center plane of the transducer device.

29. The force measuring device in accordance with claim 1, wherein sensor elements of the sensor device are arranged at the corners of a quadrilateral.

30. The force measuring device in accordance with claim 29, wherein the quadrilateral of the sensor device is congruent with a quadrilateral at the corners of which the magnetic poles lie, or the quadrilateral of the sensor device is at an angle to the quadrilateral of the magnetic poles.

31. The force measuring device in accordance with claim 29, wherein a further sensor element is arranged at a diagonal point of intersection of the quadrilateral.

32. The force measuring device in accordance with claim 1, wherein a sensor element associated with one or more magnetic poles is positioned in a projection space of the magnetic pole or poles in front of the magnetic pole or poles in the direction of the sensor device.

33. The force measuring device in accordance with claim 1, wherein the sensor elements are Hall elements.

34. The force measuring device in accordance with claim 1, wherein an evaluation device is provided for linking the signals of different sensor elements.

35. The force measuring device in accordance with claim 34, wherein the evaluation device comprises a differential unit for forming a difference between signals of different sensor elements.

36. The force measuring device in accordance with claim 34, wherein the evaluation device comprises an adding unit for adding up signals of different sensor elements.

37. The force measuring device in accordance with claim 1, wherein the transducer device or the sensor device is connected to an elastic force transducer.

38. The force measuring device in accordance with claim 37, wherein the force transducer is configured as a hollow bar.

39. The force measuring device in accordance with claim 38, wherein the transducer device and the sensor device are arranged in an interior of the hollow bar.

40. A method for evaluating signals in a force measuring device, said force measuring device comprising:
a transducer device that has a plurality of magnets and generates a magnetic field; and
a sensor device that is sensitive to a magnetic field and is arranged in a space in front of the transducer device;
wherein the transducer device and the sensor device are movable relative to each other under the action of a force;
wherein the magnets of the transducer device are positioned in a quadrupole arrangement relative to the sensor device; and
wherein the sensor device comprises at least one first sensor element and one second sensor element;
wherein the first sensor element is associated with a first magnetic pole or a first pair of magnetic poles; and
wherein the second sensor element is associated with a second magnetic pole or a second pair of magnetic poles;
said method comprising at least one of:
(i) forming a difference between signals of different sensor elements; and
(ii) measuring a magnetic field in a central region of the quadrupole arrangement by a sensor element associated with the central region; and
(iii) evaluating the signals of diagonally opposed sensor elements.

41. The method in accordance with claim 40, wherein a difference is formed with the signals of a first pair of sensor elements and the signals of a second pair of sensor elements, a direction of connection between the sensor elements of the first pair lying transversely to a direction of connection between the sensor elements of the second pair.

42. The method in accordance with claim 40, wherein the signals of four sensor elements positioned at the corners of a quadrilateral are evaluated.

43. The method in accordance with claim 40, wherein a main pole approximation is carried out.

44. The method in accordance with claim 40, wherein an addition is performed when evaluating the signals of diagonally opposed sensor elements.

45. The method in accordance with claim 40, wherein an interference field in a central region of the quadrupole arrangement is measured and taken into account in the evaluation.
